(19) United States
(12) Patent Application Publication
(10) Pub. No.: US 2009/0047788 A1
(43) Pub. Date: Feb. 19, 2009

(54) METHOD FOR FABRICATING SEMICONDUCTOR DEVICE

(75) Inventor: Jin-Ki Jung, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/163,423

(22) Filed: Jun. 27, 2008

(30) Foreign Application Priority Data
Aug. 13, 2007 (KR) 10-2007-0081120

(51) Int. Cl. H01L 21/311

(52) U.S. Cl. 438/694; 257/E21.257

(57) ABSTRACT

A method for fabricating a semiconductor device includes forming a plurality of first hard mask patterns at certain intervals over a substrate where an etch target layer is formed, forming a sacrificial layer along a step of the substrate where the first hard mask patterns are formed, forming a second hard mask layer over the sacrificial layer, etching a portion of the second hard mask layer to expose the sacrificial layer and form second hard mask patterns remaining between the first hard mask patterns, removing the sacrificial layer between the first hard mask patterns and the second hard mask patterns, and etching the etch target layer using the first hard mask patterns and the second hard mask patterns as an etch mask.

### CROSS-REFERENCE TO RELATED APPLICATIONS

The present invention claims priority of Korean patent application number 10-2007-0081120, filed on Aug. 13, 2007, which is incorporated by reference in its entirety.

### BACKGROUND OF THE INVENTION

The present invention relates to a method for fabricating a semiconductor device, and more particularly, to a method for fabricating a semiconductor device, which is capable of forming fine patterns through a one-time exposure process.

In the fabrication process of a semiconductor device, a minimum pitch for a pattern is determined by the wavelength of light used in an exposure apparatus. Thus, as the integration density of a semiconductor device rapidly increases, a wavelength for a light source in a photolithography process needs to become shorter to form patterns with smaller pitches. However, there is difficulty associated with decreasing the wavelength of the light source. Although X-ray or electron beam (E-beam) may be used to form micropatterns, these are still at an experimental level due to a technical limitation and a production limitation. As an alternate approach to overcoming such a limitation, a double exposure and etch technology (DEET) was proposed.

FIGS. 1A and 1B illustrate a conventional method for fabricating a semiconductor device using a DEET. In FIG. 1A, first photoresist patterns 3 are formed over a substrate 1 having an etch target layer (not shown). Etch target patterns 2 are formed by etching the etch target layer using the first photoresist patterns 3 as an etch mask. The first photoresist patterns 3 are then removed.

Referring to FIG. 1B, a second photoresist (not shown) is coated over the resulting structure. An exposure process and a development process are performed to expose a pattern on the etch target pattern 2. As a result, second photoresist patterns 4 are formed.

Although it is not shown, the etch target patterns 2 is etched by using the second photoresist patterns 4 as an etch mask. The second photoresist patterns 4 are then removed. In this way, the DEET process is completed.

However, when an overlay accuracy between the first photoresist patterns 3 and the second photoresist patterns 4 is low, a critical dimension (CD) of final etch target patterns changes, and thus the CD of the final etch target patterns may have poor uniformity.

Furthermore, a topology below non-planarized second photoresist patterns 4 causes a non-uniform formation of an anti-reflection coating (ARC) resulting in the deformation of the photoresist in an exposure process.

### SUMMARY OF THE INVENTION

Embodiments of the present invention relate to a method for fabricating a semiconductor device, which is capable of forming fine patterns through a one-time exposure process.

In accordance with an aspect of the present invention, there is provided a method for fabricating a semiconductor device. The method includes forming a plurality of first hard mask patterns at certain intervals over a substrate where an etch target layer is formed, forming a sacrificial layer along a step of the substrate where the first hard mask patterns are formed, forming a second hard mask layer over the sacrificial layer, etching a portion of the second hard mask layer to expose the sacrificial layer and form second hard mask patterns remaining between the first hard mask patterns, removing the sacrificial layer between the first hard mask patterns and the second hard mask patterns, and etching the etch target layer using the first hard mask patterns and the second hard mask patterns as an etch mask.

In accordance with another aspect of the present invention, there is provided a method for fabricating a semiconductor device. The method includes forming a plurality of first hard mask patterns at constant intervals over a substrate where an etch target layer is formed, forming a sacrificial layer along a step of the substrate where the first hard mask patterns are formed, selectively etching the sacrificial layer to form sacrificial patterns exposing surfaces of the first hard mask patterns, forming second hard mask patterns between the sacrificial patterns, removing the sacrificial patterns between the first hard mask patterns and the second hard mask patterns, and etching the etch target layer using the first hard mask patterns and the second hard mask patterns as an etch mask.

### BRIEF DESCRIPTION OF THE DRAWINGS

FIGS. 1A and 1B illustrate a conventional method for fabricating a semiconductor device using a double exposure and etch technology (DEET).

FIGS. 2A to 2F illustrate a method for fabricating a semiconductor device in accordance with a first embodiment of the present invention.

FIGS. 3A to 3E illustrate micrographic views of a semiconductor device in accordance with a first embodiment of the present invention.

FIGS. 4A to 4G illustrate a method for fabricating a semiconductor device in accordance with a second embodiment of the present invention.

FIG. 5 illustrates a micrographic view of a second hard mask layer in which the formation of voids is prevented.

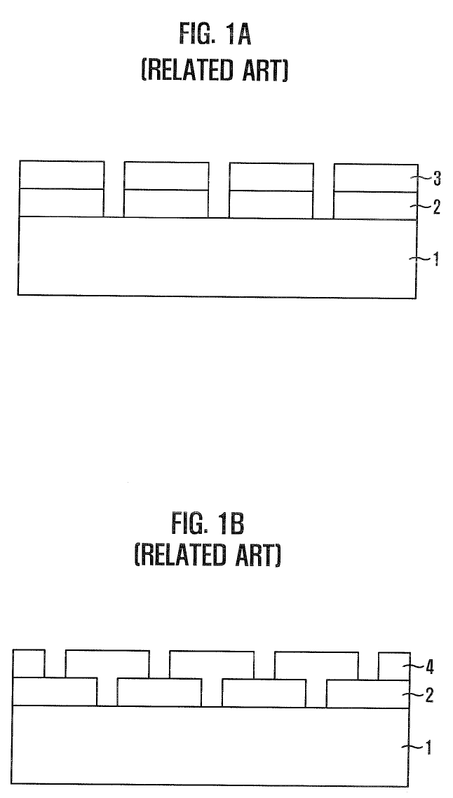

### DESCRIPTION OF SPECIFIC EMBODIMENTS

Hereinafter, a method for fabricating a semiconductor device in accordance with the present invention will be described in detail with reference to the accompanying drawings.

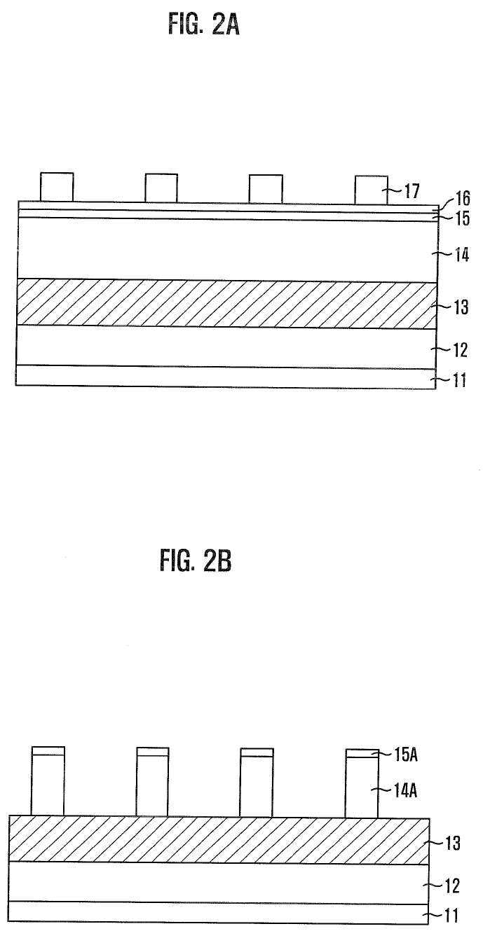

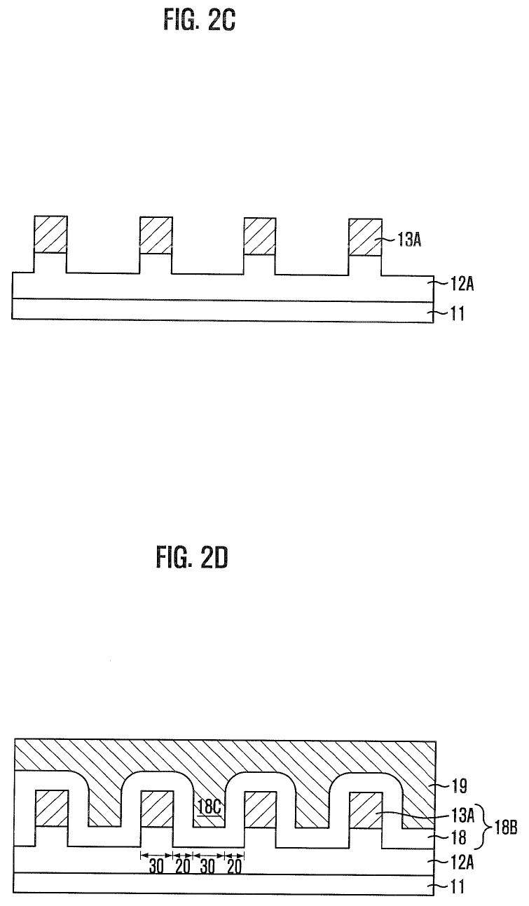

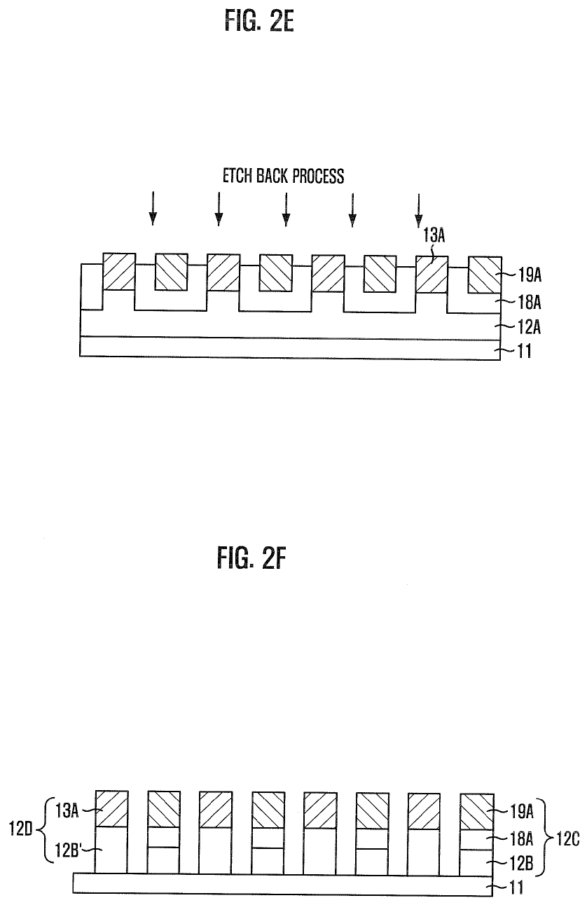

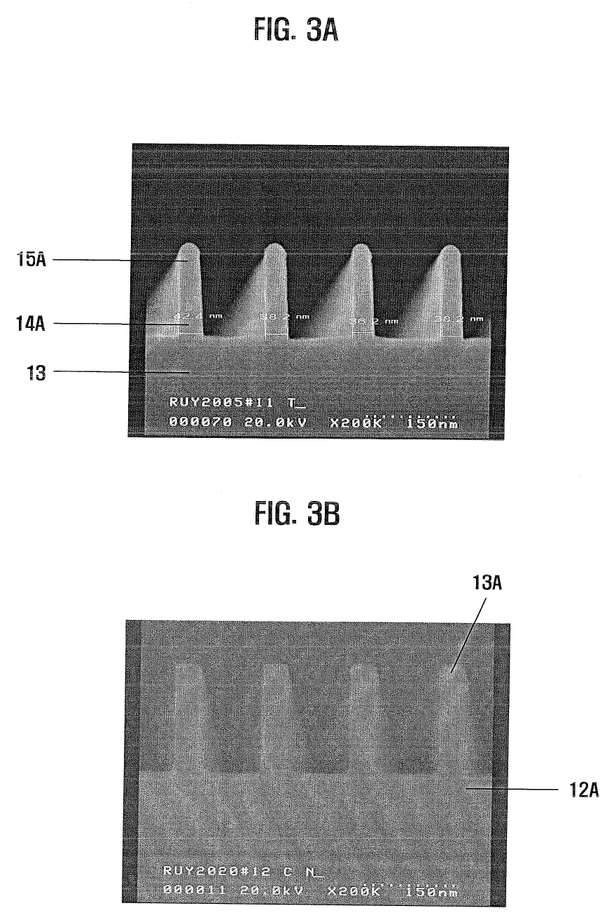

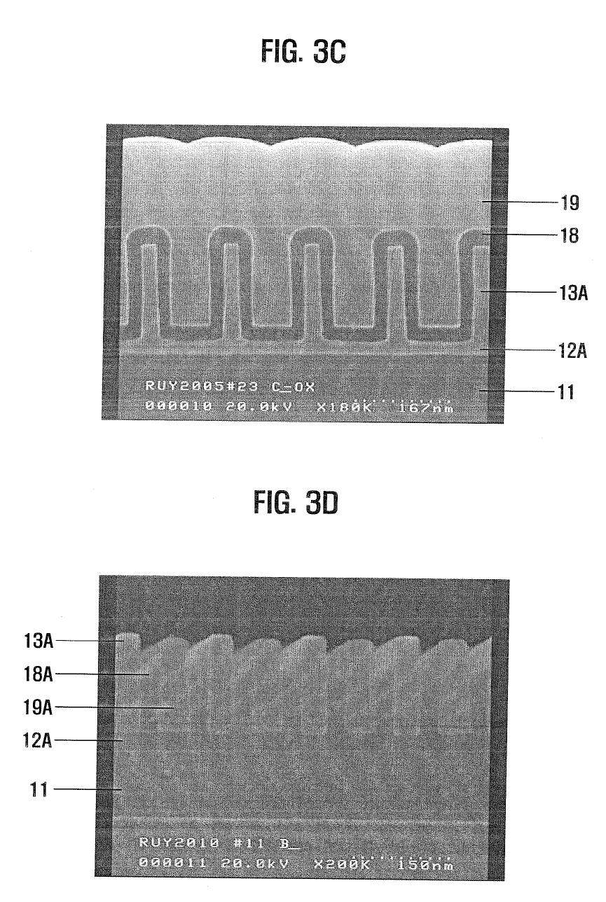

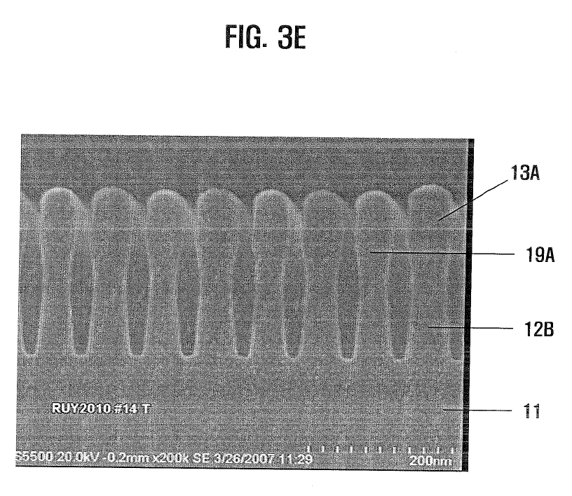

FIGS. 2A to 2F illustrate a method for fabricating a semiconductor device in accordance with a first embodiment of the present invention. FIGS. 3A to 3E are micrographic views of a semiconductor device in accordance with a first embodiment of the present invention.

In FIG. 2A, an etch target layer 12 and a first hard mask layer 13 are sequentially formed over a substrate 11. The first hard mask layer 13 serves as an etch mask layer for etching the etch target layer 12. The etch target layer 12 is formed of oxide, and the first hard mask layer 13 is formed of polysilicon.

A carbon-containing organic layer (e.g., an amorphous carbon layer 14) is formed over the first hard mask layer 13. A silicon oxynitride (SiON) layer 15, an anti-reflection layer 16, and a plurality of photoresist patterns 17 are formed over the amorphous carbon layer 14. The photoresist patterns 17 are formed by coating a photoresist and exposing and developing the coated photoresist.

Referring to FIG. 2B, the anti-reflection layer 16 and the silicon oxynitride layer 15 are etched by using the photoresist patterns 17 as an etch mask. The amorphous carbon layer 14 is etched by using the etched silicon oxynitride layer 15 as an etch mask, thereby forming silicon oxynitride patterns 15A and amorphous carbon patterns 14A.

During the etching of the amorphous carbon layer 14, the photoresist patterns 17 and the anti-reflection layer 16 (having material characteristics similar to the photoresist patterns 17) may be consumed and removed. The photoresist patterns 17 and the anti-reflection layer 16 may also be removed by a separate process.

Referring to FIG. 3A, the micrograph shows an image of a semiconductor at a stage shown in FIG. 2B. It can be seen that the amorphous carbon patterns 14A and the silicon oxynitride patterns 15A are formed over the first hard mask layer 13.

Referring to FIG. 2C, the first hard mask layer 13 is etched by using the amorphous carbon patterns 14A as an etch mask, thereby forming a plurality of first hard mask patterns 13A. At this point, a portion of the etch target layer 12 is also etched to form “etched etch target layer 12A”. This is done to accommodate a thickness of a subsequent second hard mask layer.

Referring to FIG. 3B, the micrograph shows an image of a semiconductor at a stage shown in FIG. 2C. It can be seen that the plurality of first hard mask patterns 13A are formed at constant intervals, and the etched etch target layer 12A is etched.

Referring to FIG. 2D, a sacrificial layer 18 is formed conformally over the substrate 11 and the first hard mask patterns 13A. The sacrificial layer 18 defines a plurality of structures 18B that are spaced apart at a given internal, preferably at a substantially uniform interval. These intervals define gaps 18C. The sacrificial layer 18 is formed of oxide, for example, a low pressure tetra ethyl ortho silicate (LPTEOS) or plasma enhanced chemical vapor deposition (PECVD) oxide.

A second hard mask layer 19 is formed over the sacrificial layer 18 to fill gaps 18C of defined by the structures 18B. The second hard mask layer 19 may be formed of the same material as the first hard mask patterns 13. That is, the second hard mask layer 19 may be formed of polysilicon.

Referring to FIG. 3C, the micrograph shows an image of a semiconductor at a stage shown in FIG. 2D. It can be seen that the sacrificial layer 18 is formed along steps of the first hard mask patterns 13A, and the second hard mask layer 19 is formed over the sacrificial layer 18. In one embodiment, the width of the first hard mask pattern 13A is substantially the same as the width of the gap 18C. The lateral thickness of the sacrificial layer 18 is less than the width of the gap 18C, e.g., ⅔ of the width of the gap 18C.

Referring to FIG. 2E, a portion of the second hard mask 19 and the sacrificial layer 18 are etched at least until first hard mask patterns 13A is exposed creating second hard mask patterns 19A and sacrificial pattern 18A, respectively. In one embodiment, the etch process is performed until an upper surface of the sacrificial layer 18 defined below the upper surfaces of the first hard mask pattern 13A and the second hard mask pattern 19A. One of the benefits of etching the sacrificial layer 18 until it is below the first and second hard mask patterns 13A and 19A is convenient to measure a critical dimension (CD) of the gap 18C afterwards.

In one embodiment, the etching process used is an etch-back process. For example, the sacrificial layer 18 is exposed by etching back the second hard mask layer 19, and top surfaces of the first hard mask patterns 13A are exposed by etching back the sacrificial layer 18 and the second hard mask layer 19. For convenience of a subsequent process of etching the sacrificial layer 18, the sacrificial layer 18 may be etched back to reduce the steps.

Referring to FIG. 3D, the micrograph shows an image of a semiconductor at a stage shown in FIG. 2E. It can be seen that the second hard mask patterns 19A remain between the first hard mask patterns 13A. Also, the first hard mask patterns 13A and second hard mask patterns 19A are formed to have substantially the same CD. Further, it can be seen that the sacrificial patterns 18A remain between the first hard mask patterns 13A and the second hard mask patterns 19A.

Referring to FIG. 2F, the first hard mask patterns 13A and second hard mask patterns 19A are used as a mask to etch the sacrificial patterns 18A and etched etch target layer 12A. This forms a first etch target patterns 12B and a second etch target pattern 12B′. The second etch target pattern 12B′ has a height that is higher than the first etch target pattern 12B.

The etching of the etched etch target layer 12A may be performed by a wet etching process and a dry etching process. An etch stop layer may also be previously formed under the etch target layer 12. The etch stop layer would have a lower etch rate than that of the etched etch target layer 12A. Also, the etching of the etched etch target layer 12A may be performed by a dry etching process only. The etched etch target layer 12A may be etched by using CF-based gas, for example, C₂F₆ or C₄F₈ gas.

Referring to FIG. 3E, the micrograph shows an image of a semiconductor at a stage shown in FIG. 2F. It can be seen that the etch target patterns 12B are formed as described above.

Referring back to FIG. 2F, the etch process also forms first structures 12C and second structures 12D that are alternately arranged and exposing portions of an underlying layer (not shown). The underlying layer may be the substrate 11 or a polysilicon layer (or another type of layer) provided between the substrate 11 and the etch target layer 12 according to implementation. Each first structure 12C includes the second hard mask pattern 19A, the sacrificial pattern 18A, the first etch target pattern 12B. Each second structure 12D includes the first hard mask pattern 13A and the second etch target pattern 12B′. In one embodiment, the first and second structures 12C and 12D may be used to etch the substrate 11 or the underlying layer. In another embodiment, the first and second etch target patterns 12B and 12B′ are used to etch the substrate 11 or the underlying layer. That is, the substrate 11 (or the underlying layer) is etched after removing the first hard mask patterns 13A and the second hard mask patterns 19A. In yet another embodiment, the first and second etch target patterns 12B and 12B′ themselves may be the final patterns desired. In accordance with the first embodiment of the present invention, as described above, the plurality of first hard mask patterns 13A are formed over the etched etch target layer 12A using the photoresist patterns. Then the sacrificial patterns 18A defining the gap of the etch target layer 12A is formed over the substrate 11.

The second hard mask patterns 19A are formed spaced apart from the first hard mask patterns 13A by the gap defined by the sacrificial patterns 18A, wherein the second hard mask patterns 19A is used to etch the etched etch target layer 12A with the first hard mask patterns 13A. Thus, fine patterns are formed by etching the etched etch target layer 12A using the first hard mask patterns 13A and second hard mask patterns 19A as an etch mask.

Consequently, the above-described limitations of the DEET can be overcome by forming the fine patterns through a one-time photoresist pattern forming process.

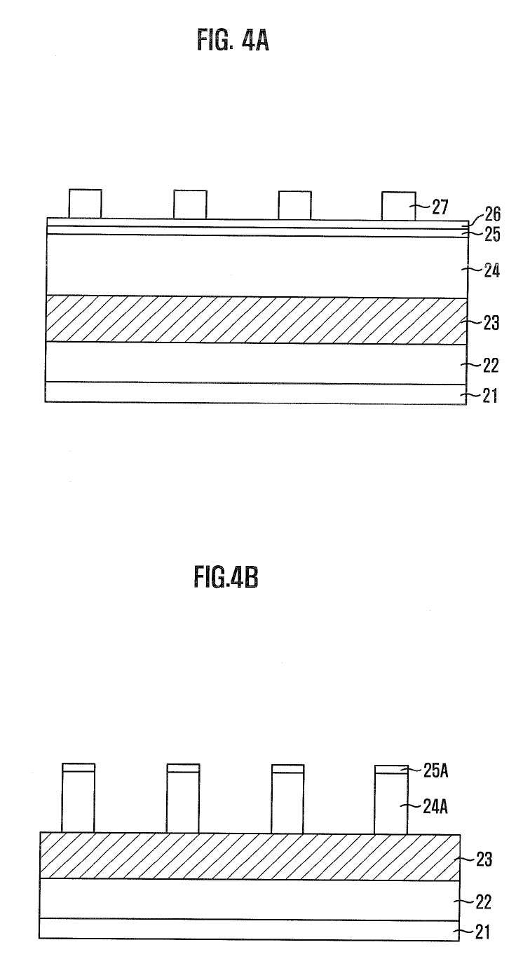

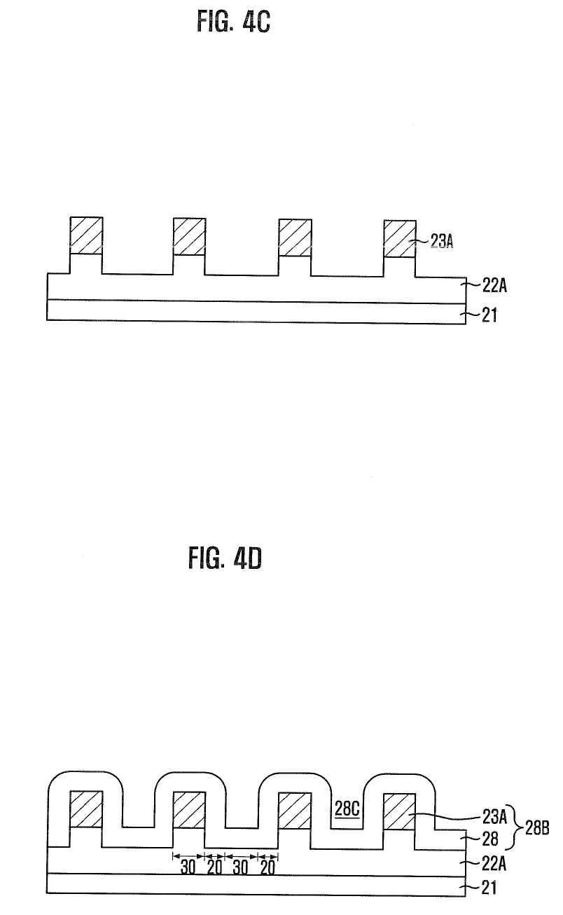

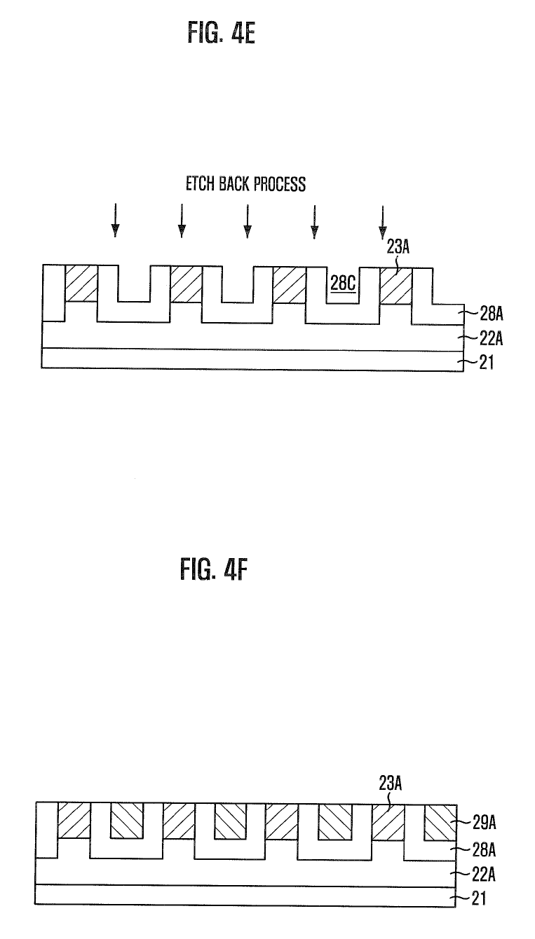

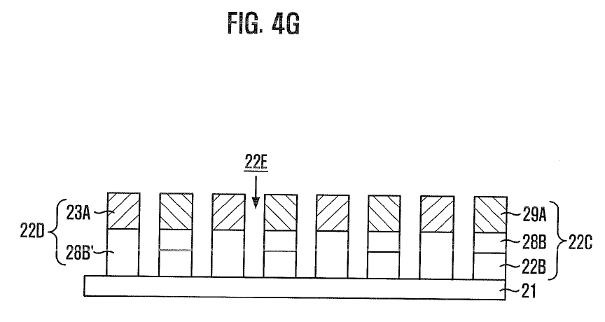

FIGS. 4A to 4G illustrate a method for fabricating a semiconductor device in accordance with a second embodiment of the present invention. In FIG. 4A, an etch target layer 22 and a first hard mask layer 23 are sequentially formed over a substrate 21 (or underlying layer). In one embodiment, the underlying layer may be any material that is provided below the etch target layer 22. The etch target layer 22 is formed of oxide, and the first hard mask layer 23 is formed of polysilicon in the present implementation.

An amorphous carbon layer 24, a silicon oxynitride (SiON) layer 25, an anti-reflection layer 26, and a photoresist patterns 27 are formed over the first hard mask layer 23. The photoresist patterns 27 are formed by coating a photoresist and exposing and developing the coated photoresist.

Referring to FIG. 4B, the anti-reflection layer 26 and the silicon oxynitride layer 25 are etched using the photoresist patterns 27 as an etch mask. This etched silicon oxynitride layer is referred to as “silicon oxynitride pattern” denoted as reference numeral 25A. The amorphous carbon layer 24 is etched by using the silicon oxynitride pattern 25A as an etch mask.

Since the silicon oxynitride pattern 25A has an exceedingly low etch rate compared to the amorphous carbon layer 24, the thick amorphous carbon layer 24 can be effectively etched by using the thin silicon oxynitride pattern 25A as an etch mask. Thus, amorphous carbon patterns 24A are formed.

During the etching of the amorphous carbon layer 24, the photoresist patterns 27 may be removed. The photoresist patterns 27 may also be removed by a separate process.

Referring to FIG. 4C, the first hard mask layer 23 is etched by using the amorphous carbon patterns 24A as an etch mask, thereby a first hard mask patterns 23A are formed. At this point, a portion of the etch target layer 22 is also etched in order to accommodate a thickness of a subsequent second hard mask layer. Thus, an etched etch target layer 22A is formed having a plurality of shallow trenches.

Referring to FIG. 4D, a sacrificial layer 28 is formed conformally over the substrate 21 and the first hard mask patterns 23A. The sacrificial layer 28 defines a plurality of structures 28B that are spaced apart at a given internal, preferably at a substantially uniform interval. These intervals define gaps 28C. The sacrificial layer 28 has a high etch ratio with respect to the first hard mask patterns 23A. When the first hard mask patterns 23A are formed of polysilicon, the sacrificial layer 28 may be formed of oxide.

Referring to FIG. 4E, the sacrificial layer 28 is etched by an etch-back process, thereby forming sacrificial patterns 28A. The etch-back process is performed for reducing an aspect ratio of the gaps 28C defined by the sacrificial layer 28. The etch-back process may be performed until the top surfaces of the first hard mask patterns 23A are exposed and the aspect ratio of the gaps 28C is sufficiently lowered to enable a second hard mask layer that will be formed later to fill the gaps 28C without voids. In one embodiment, a chemical mechanical polishing (CMP) process is used to etch the sacrificial layer 28 and reduce the aspect ratio of the gaps 28C.

Referring to FIG. 4F, a second hard mask layer (not shown) is formed to fill the gaps 28C. An upper portion of the second hard mask layer is etched back to form a second hard mask patterns 29A. The second hard mask patterns 29A may be formed of the same material as the first hard mask patterns 23A (e.g., polysilicon).

The second hard mask patterns 29A preferably have the same CD as the first hard mask patterns 23A. The deposition thickness of the sacrificial layer 28 is configured to have substantially the same dimension as a gap 22E (see FIG. 4G) between the etch target patterns when the etch target layer is etched. Therefore, the sacrificial patterns should be formed considering the above-described relationship.

For example, when a gap 22E between etch target patterns is set to “20”, the sacrificial pattern 28 should have the width of “20”. When a region A (not shown) where two etch target patterns are formed should have the width of “100”, the first hard mask pattern 23A and the second hard mask pattern 29A should have a width of “30”. Herein, the units are omitted.

Referring to FIG. 4G, the sacrificial patterns 28A and the etched etch target layer 22A are etched using the second hard mask patterns 29A and the first hard mask patterns 23A as an etch mask, thereby forming etched sacrificial patterns 28B, first etch target patterns 22B, and second etch target patterns 22B′. Then, the first hard mask patterns 23A and the second hard mask patterns 29A are removed.

The etching of the etch target layer 22A may be performed by a wet etching process and a dry etching process. An etch stop layer may be previously formed underneath the etch target layer 22. Also, the etching of the etch target layer 22A may be performed by a dry etching process only. The etch target layer 22A may be etched by using CF-based gas, for example, C₂F₆ or C₄F₈ gas.

As shown in FIG. 4G, the etch process also forms first structures 22C and second structures 22D that are alternately arranged and exposing portions of an underlying layer (not shown). A gap 22E is defined between the first and second structures 22C and 22D and exposing the underlying layer 21. Each first structure 22C includes the second hard mask pattern 29A, the etched sacrificial pattern 28B, the first etch target pattern 22B. Each second structure 22D includes the first hard mask pattern 23A and the second etch target pattern 22B′. In one embodiment, the first and second structures 22C and 22D are used as an etch mask. In another embodiment, the first and second etch target patterns 22B and 22B′ are used as an etch mask after removing the first and second hard mask patterns 23A and 29A.

In accordance with the second embodiment of the present invention, as described above, the first hard mask patterns 23A are formed over the etched etch target layer 22A using the photoresist patterns. The sacrificial patterns 28A defining the gap of the etched etch target layer 22A are formed over the substrate 21. A planarization process may be performed for reducing an aspect ratio of the gaps 28C.

The second hard mask patterns 29A (or first structure 22C) and the first hard mask patterns 23A (or second structure 22D) are formed spaced apart from each other by the gap 22E defined by the sacrificial patterns 28A. Thus, the fine patterns are formed by etching the etched etch target layer 22A using the first hard mask patterns 23A and second hard mask patterns 29A as an etch mask.

Consequently, the above-described limitations of the DEET can be solved by forming the fine patterns through a one-time photoresist pattern forming process.

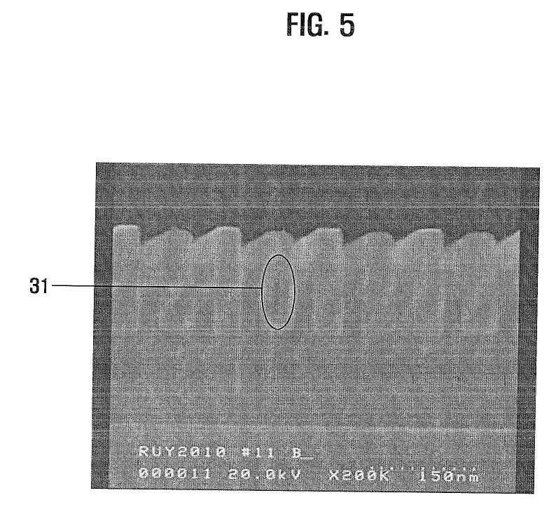

Meanwhile, referring to FIG. 5, high aspect ratio between a plurality of sacrificial layers 28 (or gaps 28C) can generate a void 31 while forming the second hard mask layer. The void 31 acts to reduce an etching barrier margin of the second hard mask layer.

However, in accordance with the second embodiment of the present invention, the void can be avoided while forming the second hard mask layer by reducing the aspect ratio of the gaps 28C. Consequently, the etching barrier margin of the second hard mask layer can be sufficiently secured.

In accordance with the embodiments of the present invention, the limitations of the DEET technology can be overcome because the fine patterns are formed by a one-time exposure process. Therefore, it is possible to meet a required size of the fine patterns, thereby increasing the stability and reliability of the semiconductor device.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
forming a plurality of first hard mask patterns over an etch target layer provided over a substrate;
forming a sacrificial layer over the first hard mask patterns, the sacrificial layer being conformal to the first hard mask patterns and defining a plurality of structures and a plurality of gaps;
forming a second hard mask layer over the sacrificial layer, the second hard mask layer filling the gaps;
etching an upper portion of the second hard mask layer to form second hard mask patterns defined within the gaps, the sacrificial layer being exposed between the first hard mask patterns and the second hard mask patterns;
removing the exposed sacrificial layer between the first hard mask patterns and the second hard mask patterns, the etch target layer being exposed between the first hard mask patterns and the second hard mask patterns; and
etching the exposed etch target layer using the first hard mask patterns and the second hard mask patterns as an etch mask to form first and second etch target patterns.

2. The method of claim 1, wherein the first hard mask patterns and the second hard mask patterns have substantially the same width.

3. The method of claim 1, wherein the upper portion of the second hard mask layer is etched by using an etch back process.

4. The method of claim 1, wherein the plurality of first hard mask patterns are patterned by using photoresist patterns.

5. The method of claim 1, wherein a portion of the etch target layer is etched when the first hard mask patterns are formed, so that the etch target layer is provided with a plurality of shallow trenches.

6. The method of claim 1, wherein the first hard mask patterns and the second hard mask patterns include polysilicon, and the etch target layer includes oxide.

7. The method of claim 1, wherein the sacrificial layer comprises a low pressure tetra ethyl ortho silicate (LPTEOS) layer or a plasma enhanced chemical vapor deposition (PECVD) oxide layer.

8. A method for fabricating a semiconductor device, the method comprising:
forming a plurality of first hard mask patterns over an etch target layer provided over a substrate, the first hard mask patterns having a first pitch;
forming a sacrificial layer over the first hard mask patterns in a conformal manner, the sacrificial layer defining a plurality of structures and a plurality of gaps;
etching the sacrificial layer to form sacrificial patterns exposing surfaces of the first hard mask patterns;
forming a second hard mask layer over the sacrificial patterns and within the gaps;
removing an upper portion of the second hard mask layer to form second hard mask patterns between the sacrificial patterns and within the gaps, the sacrificial patterns being exposed between the first hard mask patterns and the second hard mask patterns;
removing the sacrificial patterns exposed between the first hard mask patterns and the second hard mask patterns, the etch target layer being exposed between the first hard mask patterns and the second hard mask patterns; and
etching the exposed etch target layer using the first hard mask patterns and the second hard mask patterns as an etch mask to form a plurality of etch target patterns having a second pitch that is less than the first pitch.

9. The method of claim 8, wherein the first hard mask patterns and the second hard mask patterns are formed to have substantially the same critical dimension.

10. The method of claim 8, wherein two adjacent etch target patterns define a gap that corresponds to a width of the sacrificial layer.

11. The method of claim 8, wherein the plurality of first hard mask patterns are formed by using photoresist patterns.

12. The method of claim 8, wherein a portion of the etch target layer is etched when the first hard mask patterns are formed, so that the etch target layer is provided with a plurality of shallow trenches.

13. The method of claim 8, wherein the first hard mask patterns and the second hard mask patterns include polysilicon, and the etch target layer includes oxide.

14. The method of claim 8, further comprising:
forming a first hard mask layer over the etch target layer;
forming a carbon-containing layer over the first hard mask layer;
forming a silicon oxynitride layer over the carbon-containing layer; and
forming photoresist patterns over the silicon oxynitride layer.

15. The method of claim 14, further comprising:
etching the silicon oxynitride layer using the photoresist patterns as a mask; and
etching the carbon-containing layer using the etched silicon oxynitride layer as a mask,
wherein the first hard mask patterns are formed by etching the first hard mask layer using the etched carbon-containing layer as a mask.

16. The method of claim 8, wherein a width of the gaps defined by the sacrificial layer is substantially the same as a width of the first hard mask pattern.
